(19) United States
(12) Patent Application Publication
(10) Pub. No.: US 2025/0220901 A1
(43) Pub. Date: Jul. 3, 2025

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Young Ji NOH, Suwon-si (KR); Kwang-Soo KIM, Suwon-si (KR)

(21) Appl. No.: 18/922,643

(22) Filed: Oct. 22, 2024

(30) Foreign Application Priority Data
Dec. 28, 2023 (KR) 10-2023-0195098

(51) Int. Cl. H10B 43/20; H10B 43/10; H10B 43/35; H10B 43/40

(52) U.S. Cl. CPC H10B 43/20; H10B 43/10; H10B 43/35; H10B 43/40

(57) ABSTRACT

A semiconductor memory device includes a cell substrate; a mold structure which includes word lines, a voltage bias film, and a string selection line stacked sequentially on the cell substrate; a channel hole which penetrates the mold structure; and a channel structure inside the channel hole, wherein the channel hole includes a first portion penetrating the word line, a second portion penetrating the voltage bias film, and a third portion penetrating the string selection line, a width of a lowermost part of the second portion is greater than a width of an uppermost part of the first portion, and a width of an uppermost part of the second portion is greater than a width of a lowermost part of the third portion.

### CROSS-REFERENCE TO RELATED APPLICATION

This application claims priority from Korean Patent Application No. 10-2023-0195098filed on Dec. 28, 2023, in the Korean Intellectual Property Office, and all the benefits accruing therefrom under 35 U.S.C. 119, the contents of which in its entirety are herein incorporated by reference.

### BACKGROUND

### 1. Field of the Invention

The present invention relates to a semiconductor memory device and an electronic system including the same. More specifically, the present invention relates to a semiconductor memory device including three-dimensionally arranged memory cells and an electronic system including the same.

### 2. Description of the Related Art

As the integration density of nonvolatile memory devices is increasing in order to satisfy requirements driven by electronic systems, technologies for increasing the data storage capacity are being researched. In a two-dimensional or planar memory device, the integration density is determined based on an area occupied by a unit memory cell. Accordingly, a three-dimensional memory device, in which unit memory cells are vertically arranged, has been proposed.

### SUMMARY

Aspects of the present invention provide a semiconductor memory device having improved characteristics.

Aspects of the present invention also provide an electronic system including the semiconductor memory device having improved characteristics.

However, aspects of the present invention are not restricted to the one set forth herein. The above and other aspects of the present disclosure will become more apparent to one of ordinary skill in the art to which the present disclosure pertains by referencing the detailed description of the present invention given below.

According to an aspect of the present invention, a semiconductor memory device includes a cell substrate and a cell array assembly which includes word lines, a voltage bias film, and a string selection line (SSL) stacked sequentially on the cell substrate. The semiconductor memory device further includes a channel hole which penetrates the cell array assembly and a composite storage layer inside the channel hole. The channel hole includes a first portion penetrating the word lines, a second portion penetrating the voltage bias film, and a third portion penetrating the SSL. A width of a lowermost part of the second portion is greater than a width of an uppermost part of the first portion, and a width of an uppermost part of the second portion is greater than a width of a lowermost part of the third portion.

According to another aspect of the present invention, a semiconductor memory device includes a cell substrate and a cell array assembly which includes word lines, a voltage bias film, and a string select line (SSL) stacked sequentially on the cell substrate. The semiconductor memory device further includes a channel hole which penetrates the cell array assembly, a composite storage layer which includes a channel layer extending along the channel hole, and a channel pad connected to the channel layer on the composite storage layer. A vertical center of a first portion of the channel hole penetrating the word lines is shifted from a vertical center of a second portion of the channel hole penetrating the SSL.

According to another aspect of the present invention, an electronic system includes a main board, a semiconductor memory device on the main board and a controller on the main board, and electrically connected to the semiconductor memory device. The semiconductor memory device includes a cell substrate, a cell array assembly which includes word lines, a voltage bias film, and a string select line (SSL) stacked sequentially on the cell substrate. The semiconductor memory device further includes a channel hole which penetrates the cell array assembly, a composite storage layer which includes a channel layer extending along the channel hole, and a channel pad connected to the channel layer, on the composite storage layer. The voltage bias film includes a material different from the SSL, and a minimum width of a portion of the channel hole that penetrates the SSL is smaller than a maximum width of a portion of the channel hole that penetrates the voltage bias film.

According to another aspect of the present invention, a semiconductor memory device includes a cell substrate and a cell array assembly which includes word lines, a voltage bias film and a string select line (SSL) stacked sequentially on the cell substrate. The semiconductor memory device further includes a channel hole which penetrates the cell array assembly and a channel layer in the channel hole. The channel layer extends along a side wall of the channel hole, the channel layer is formed conformally along the side wall of the channel hole, and the channel layer intersects the word lines, the voltage bias film and the SSL in a vertical direction.

### BRIEF DESCRIPTION OF THE DRAWINGS

The above and other aspects and features of the present invention will become more apparent by describing in detail exemplary embodiments thereof with reference to the attached drawings, in which:

FIG. 1 is an exemplary block diagram for explaining a semiconductor memory device according to some embodiments;

FIG. 2 is an exemplary circuit diagram for explaining a semiconductor memory device according to some embodiments;

FIG. 3 is a schematic layout diagram for explaining a semiconductor memory device according to some embodiments;

FIG. 4 is a cross-sectional view taken along line A-A of FIG. 3;

FIG. 5 is an enlarged view for explaining a region R1 of FIG. 4;

FIG. 6 is an enlarged view for explaining a region R2 of FIG. 5;

FIG. 7 is an enlarged view for explaining a region R3 of FIG. 5;

FIGS. 8 to 12 are diagrams for explaining a semiconductor memory device according to some embodiments;

FIG. 13 is a diagram for explaining a semiconductor memory device according to some embodiments;

FIG. 14 is an enlarged view of a region R4 of FIG. 13;

FIGS. 15 to 21 are intermediate step diagrams for explaining a method for fabricating a semiconductor memory device according to some embodiments;

FIG. 22 is an example block diagram for explaining an electronic system according to some embodiments;

FIG. 23 is an exemplary perspective view for explaining an electronic system according to some embodiments; and

FIG. 24 is a schematic cross-sectional view taken along I-I of FIG. 23.

### DETAILED DESCRIPTION OF THE EMBODIMENTS

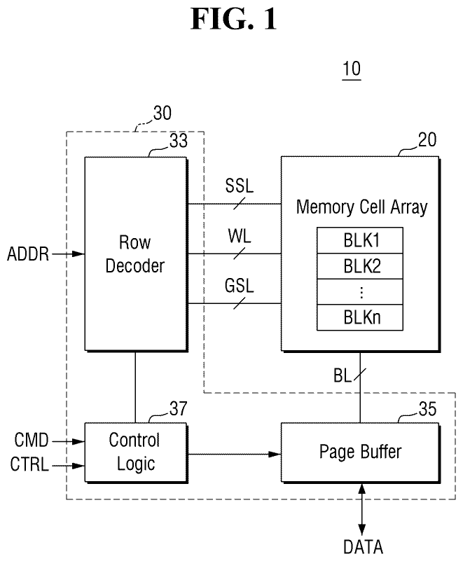

FIG. 1 is an exemplary block diagram for explaining a semiconductor memory device according to some embodiments.

Referring to FIG. 1, a semiconductor memory device 10 according to some embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL and the ground selection line GSL. Further, the memory cell blocks BLK1 to BLKn may be connected to a page buffer 35 through the bit line BL.

The peripheral circuit 30 may receive an address ADDR, a command CMD and a control signal CTRL from the outside of the semiconductor memory device 10, and may transmit and receive data DATA to and from an external device of the semiconductor memory device 10. The peripheral circuit 30 may include a control logic 37, a row decoder 33 and a page buffer 35. Although not shown, the peripheral circuit 30 may further include various sub-circuits, such as an input/output (I/O) circuit, a voltage generation circuit that generates various voltages necessary for the operation of the semiconductor memory device 10, and an error correction circuit for correcting error of the data DATA that is read from the memory cell array 20.

The control logic 37 may be connected to the row decoder 33, the input/output circuit and the voltage generation circuit. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word line WL and the bit line BL when performing a memory operation such as a program operation or an erase operation. It should be noted that items described in the singular herein, may be provided in plural, as can be seen in the various figures from the context in which they are described.

The row decoder 33 may select at least one of the plurality of memory cell blocks BLK1 to BLKn in response to the address ADDR, and may select at least one word line WL, at least one string selection line SSL, and at least one ground selection line GSL of the selected one of the memory cell blocks BLK1 to BLKn. The row decoder 33 may transfer a voltage for performing the memory operation to the word lines WL of the selected one of the memory cell blocks BLK1 to BLKn.

The page buffer 35 may be connected to the memory cell array 20 through the bit line BL. The page buffer 35 may operate as a write driver or a sense amplifier. Specifically, when performing the program operation, the page buffer 35 may operate as the write driver to apply a voltage according to the data DATA to be stored in the memory cell array 20 to the bit line BL. On the other hand, when performing the read operation, the page buffer 35 may operate as a sense amplifier to sense the data DATA stored in the memory cell array 20.

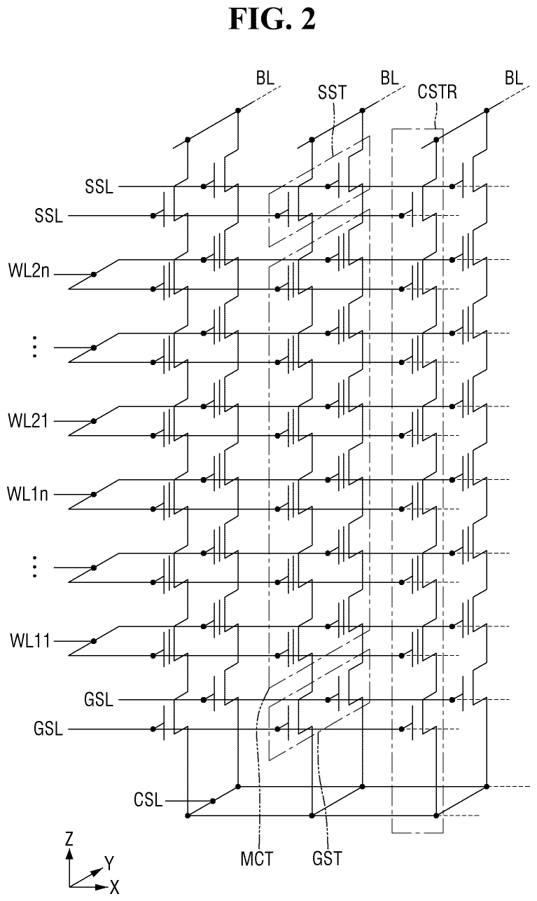

FIG. 2 is an exemplary circuit diagram for explaining a semiconductor memory device according to some embodiments.

Referring to FIG. 2, a memory cell array (e.g., 20 of FIG. 1) of the semiconductor device according to some embodiments may include a common source line CSL, the bit lines BL and a plurality of cell strings CSTR.

The plurality of bit lines BL may be arranged two-dimensionally in a plane parallel to an X-Y plane (i.e., a plane extending along a first direction X and a second direction Y).

For example, the bit lines BL are spaced apart from each other and arranged along the first direction X, and may each extend in the second direction Y. The plurality of cell strings CSTR may be connected in parallel to each bit line BL. The cell strings CSTR may be commonly connected to the common source line CSL. The plurality of cell strings CSTR may be disposed between the bit lines BL and the common source line CSL.

Each cell string CSTR may include a ground selection transistor GST connected to the common source line CSL, a string selection transistor SST connected to the bit line BL, and a plurality of memory cell transistors MCT disposed between the ground selection transistor GST and the string selection transistor SST. Each memory cell transistor MCT may include a data storage element. The ground selection transistor GST, the string selection transistor SST and the memory cell transistors MCT may be connected in series.

The common source line CSL may be commonly connected to sources of the ground selection transistors GST. Also, the ground selection line GSL, the plurality of word lines WL11 to WL1n and WL21 to WL2n (also designated collectively as WL in FIG. 1), and the string selection line SSL may be disposed between the common source line CSL and the bit line BL. The ground selection line GSL may be used as a gate electrode of the ground selection transistor GST, the word lines WL11 to WL1n and WL21 to WL2n may be used as gate electrodes of the memory cell transistors MCT, and the string selection line SSL may be used as the gate electrode of the string selection transistor SST.

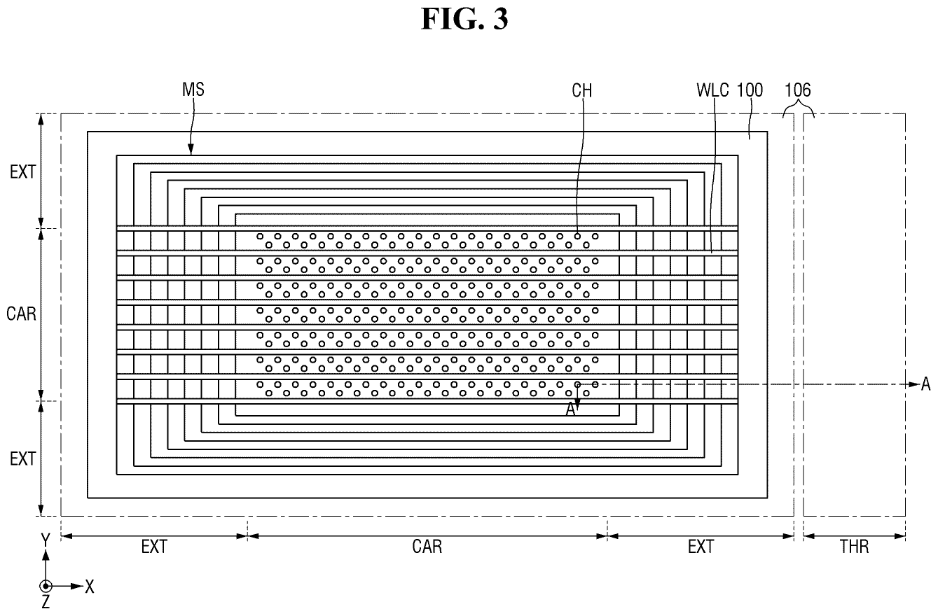

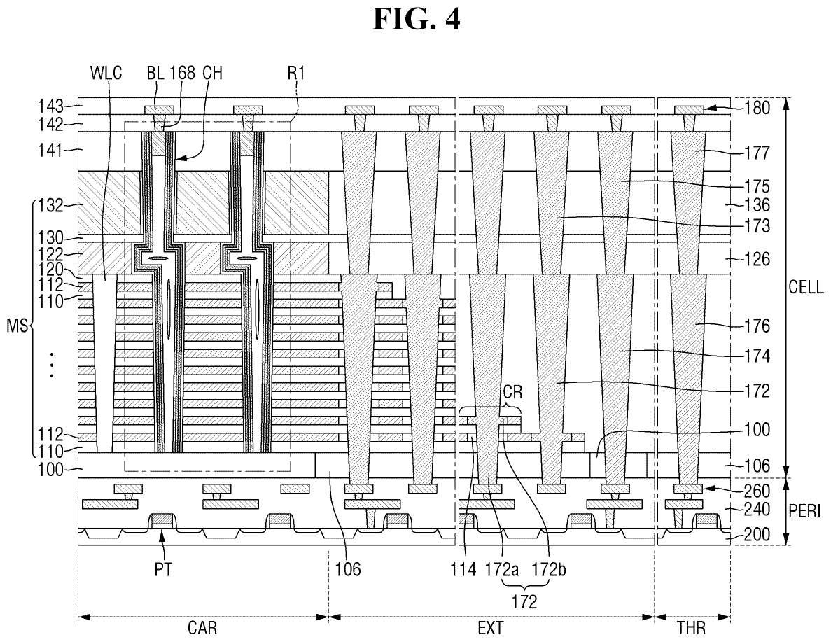

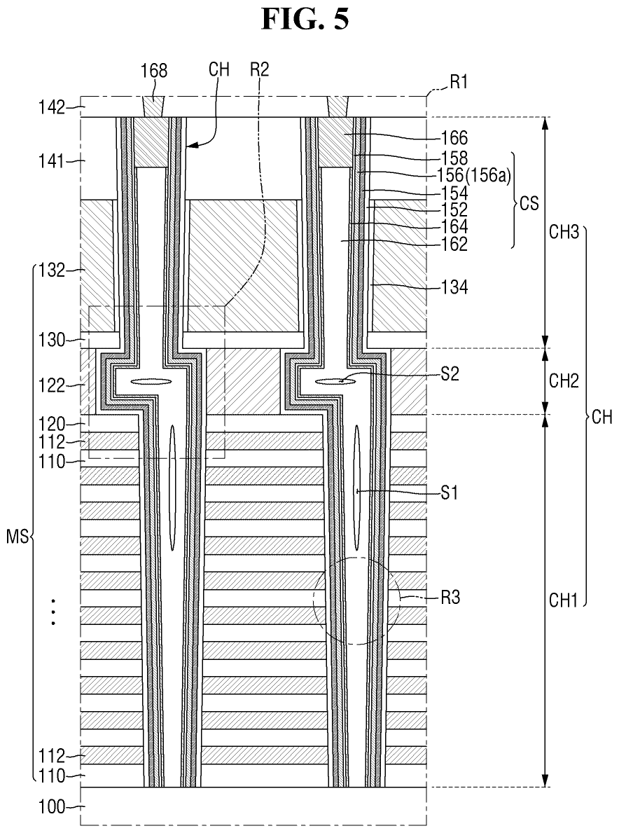

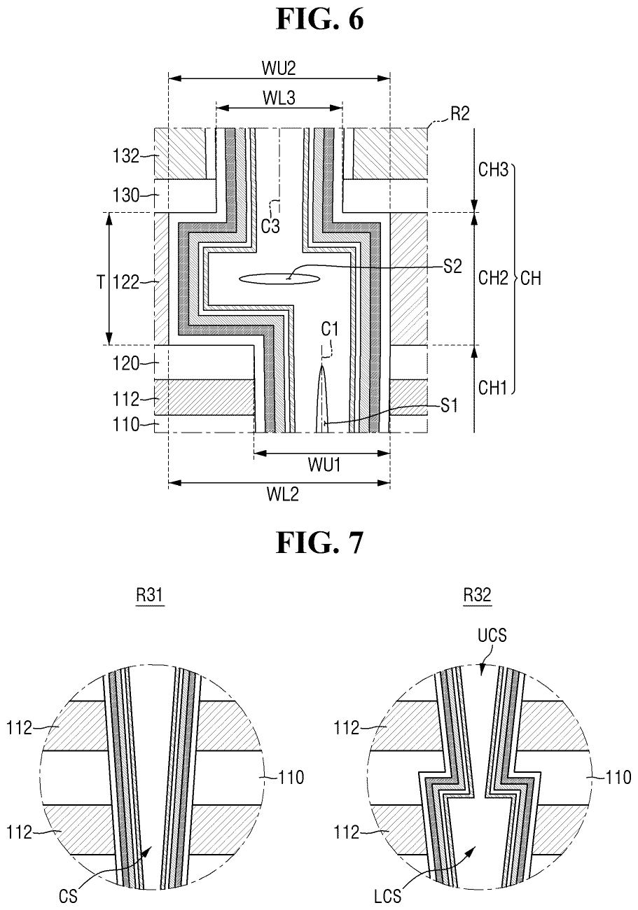

FIG. 3 is a schematic layout diagram for explaining a semiconductor memory device according to some embodiments. FIG. 4 is a cross-sectional view taken along line A-A of FIG. 3. FIG. 5 is an enlarged view for explaining a region R1 of FIG. 4. FIG. 6 is an enlarged view for explaining a region R2 of FIG. 5. FIG. 7 is an enlarged view for explaining a region R3 of FIG. 5.

Referring to FIGS. 3 to 7, the semiconductor memory device according to some embodiments includes a cell structure CELL and a peripheral circuit structure PERI.

The cell structure CELL may include a cell substrate 100, an insulating substrate 106, a mold structure MS (also referred to as “cell array assembly”), a channel structure CS, a word line cutting structure WLC, a bit line BL, a cell contact 172, and a cell wiring structure 180.

The cell substrate 100 may include a semiconductor substrate, for example, such as a silicon substrate, a germanium substrate or a silicon-germanium substrate. Alternatively, the cell substrate 100 may include a silicon-on-insulator (SOI) substrate, a germanium-on-insulator (GOI) substrate, or the like.

In some embodiments, the cell substrate 100 may include impurities. For example, the cell substrate 100 may include N-type impurities (e.g., phosphorus (P), arsenic (As) or the like). In the following description, although the cell substrate 100 will be mainly described as being of an N type, this is merely an example, and it goes without saying that the cell substrate 100 may be of a P type. In some embodiments, the cell substrate 100 may include polysilicon (poly—Si) doped with N-type impurities. Such a cell substrate 100 may be provided as a common source line (e.g., CSL of FIG. 2) of the semiconductor memory device according to some embodiments.

The cell substrate 100 may include a cell array region CAR, an extension region EXT, and a through region THR.

The memory cell array (e.g., 20 of FIG. 1) including a plurality of memory cells may be formed on the cell array region CAR. For example, a channel structure CS, gate electrodes 112, a bit line BL, and the like, which will be described below, may be disposed on the cell array region CAR. In the following description, a surface of the cell substrate 100 on which the memory cell array is disposed may be referred to as a front side. In contrast, a surface of the cell substrate 100 opposite to the front side of the cell substrate 100 may be referred to as a back side of the cell substrate 100.

The extension region EXT may be disposed around the cell array region CAR. For example, the extension region EXT may surround the cell array region CAR from a planar point of view. The gate electrodes 112 may be stacked on the extension region EXT in a stepwise manner.

For example, the gate electrodes 112 may extend to different lengths in the first direction X and have steps. Therefore, each gate electrode 112 may include a connecting region CR whose upper side is exposed on the extension region EXT. The connecting region CR may be disposed at the end portion of each gate electrode 112. The gate electrodes 112 may also extend in the second direction Y to different lengths and have steps.

The through region THR may be disposed outside the cell array region and/or extension region EXT, or may be disposed inside the cell array region and/or the extension region EXT. An I/O contact 176 may be disposed on the through region THR.

The insulating substrate 106 may be formed in at least a part of the cell substrate 100 in the extension region EXT and/or the through region THR. The insulating substrate 106 may form an insulating region inside the cell substrate 100 in the extension region EXT and/or the through region THR. As an example, the insulating substrate 106 may replace at least a part of the cell substrate 100 of the through region THR to define an insulating region inside the through region THR. The insulating substrate 106 may include, for example, but not limited to, at least one of silicon oxide, silicon nitride, silicon oxynitride, and silicon carbide.

The cell array assembly MS (i.e., mold structure) may be formed on the cell substrate 100.

The mold structure MS may include mold insulating films 110, gate electrodes 112, a first interlayer insulating film 120, a conductive film 122, a second interlayer insulating film 126, a string selection line 132 (e.g., SSL of FIG. 2). The gate electrodes 112, the conductive film 122 (also referred to as a “voltage bias film”), and the string selection line 132 may be sequentially stacked on the cell substrate 100.

The mold insulating films 110 and the gate electrodes 112 may be alternately stacked on the cell substrate 100. Each gate electrode 112 and each mold insulating film 110 may have a layered structure extending parallel to the upper side of the cell substrate 100 (on the basis of the third direction Z). The gate electrodes 112 are spaced apart from each other by the mold insulating film 110, and may be sequentially stacked on the cell substrate 100. Hereinafter, the upper side, the lower side, the upper part, and the lower part are defined on the basis of a direction (third direction Z) toward the cell structure CELL in the peripheral circuit structure PERI.

In some embodiments, the gate electrodes 112 may include at least one ground selection line (e.g., GSL of FIG. 2) and a plurality of word lines (e.g., WL11 to WL1n and WL21 to WL2n of FIG. 2) that are stacked sequentially on the cell substrate 100. The number, placement and the like of the mold insulating film 110 and the gate electrode 112 are merely exemplary, and are not limited to the shown example. The number of string selection lines 132 is exemplary only and is not limited to the shown example.

The gate electrodes 112 may each include a conductive material, for example, but not limited to, a metal such as tungsten (W), molybdenum (Mo), ruthenium (Ru), cobalt (Co), and nickel (Ni), or a semiconductor material such as silicon. As an example, the gate electrodes 112 may each include at least one of tungsten (W), molybdenum (Mo), and ruthenium (Ru). As another example, the gate electrodes 112 may each include polysilicon.

Each of the mold insulating films 110 may include, for example, but not limited to, at least one of silicon oxide, silicon nitride, and silicon oxynitride. As an example, each of the mold insulating films 110 may include a silicon oxide film. The first interlayer insulating film 120 may cover the mold insulating films 110 and the gate electrodes 112 which are alternately stacked.

The conductive film 122 and the second interlayer insulating film 126 may be disposed on the first interlayer insulating film 120. The second interlayer insulating film 126 may be disposed on the first interlayer insulating film 120 on which the conductive film 122 is not disposed. For example, the conductive film 122 may be disposed on the cell array region CAR, and the second interlayer insulating film 126 may be provided in the cell array region CAR, the extension region EXT, and the through region THR. The end portion of the conductive film 122 may be provided, for example, in the cell array region CAR. As another example, the end portion of the conductive film 122 may be disposed between the channel structure CS and the cell contact 172 that are closest to each other.

The conductive film 122 may include or be formed of a conductive material. The conductive film 122 includes or be formed of a material different from the string selection line 132. The conductive film 122 may include or be formed of, for example, tungsten (W).

The third interlayer insulating film 130 may cover the conductive film 122 and the second interlayer insulating film 126.

The string selection line 132 and the fourth interlayer insulating film 136 may be disposed on the third interlayer insulating film 130. The fourth interlayer insulating film 136 may be disposed on the third interlayer insulating film 130 on which the string selection line 132 is not disposed. For example, the string selection line 132 may be disposed on the cell array region CAR, and the fourth interlayer insulating film 136 may be provided in the cell array region CAR, the extension region EXT, and the through region THR. The end portion of the string selection line 132 may be provided, for example, in the cell array region CAR. As another example, the end portion of the string selection line 132 may be disposed between the channel structure CS and the cell contact 172 that are closest to each other. At least a part of the string selection line 132 may overlap the conductive film 122 in the third direction Z.

For example, a thickness of the string selection line SSL (on the basis of the direction perpendicular to the upper side of the cell substrate 100) may be thicker than thicknesses of each of the gate electrodes GSL, WL1 to WLn, and ECL. Hereinafter, the thickness is defined on the basis of a direction (for example, the third direction Z) perpendicular to the upper side of the cell substrate 100.

The string selection line 132 may include or be formed of a conductive material. The string selection line 132 may include or be formed of a semiconductor material, such as polycrystalline silicon or single crystal silicon, and the semiconductor material may be an undoped material or a material including p-type or n-type impurities. The string selection line 132 may include or be formed of, for example, polysilicon.

In some embodiments, an SSL protection film 134 may be interposed between the string selection line 132 and the channel structure CS. The SSL protection film 134 may be an oxide film obtained by oxidizing the string selection line 132.

The first cell insulating film 141, the second cell insulating film 142, and the third cell insulating film 143 may be sequentially stacked on the string selection line 132 and the fourth interlayer insulating film 136.

The first to fourth interlayer insulating films 120, 126, 130 and 136 and the first to third cell insulating films 141, 142 and 143 may each include or be formed of, but not limited to, at least one of silicon oxide, silicon oxynitride, and a low dielectric constant (low-k) material having a lower dielectric constant than silicon oxide.

The channel hole CH may be formed on the cell array region CAR of the cell substrate 100. The channel hole CH may extend in the vertical direction (hereinafter referred to as the third direction Z) that intersects the upper side of the cell substrate 100 inside the mold structure MS. The channel hole CH may penetrate the mold structure MS. For example, the channel hole CH may have a pillar shape (for example, a cylindrical shape) extending in the third direction Z.

The channel hole CH may include a first portion CH1 penetrating the gate electrode 112, a second portion CH2 penetrating the conductive film 122, and a third portion CH3 penetrating the string selection line 132.

The first portion CH1 may penetrate the gate electrodes 112, the mold insulating films 110, and the first interlayer insulating film 120 which are alternately stacked. For example, a width of the first portion CH1 (on the basis of the direction parallel to the upper side of the cell substrate 100) may decrease toward the cell substrate 100. Hereinafter, the width is defined on the basis of the direction parallel to the upper side of the cell substrate 100.

The second portion CH2 may penetrate the conductive film 122. The width of the second portion CH2 may decrease toward the cell substrate 100 or may be substantially the same.

The third portion CH3 may penetrate the third interlayer insulating film 130, the string selection line 132, and the first cell insulating film 141. For example, the width of the third portion CH3 may decrease toward the cell substrate 100.

Referring to FIG. 6, the side wall of the channel hole CH includes a step. For example, the side wall of the channel hole CH may have a step at a boundary between the first portion CH1 and the second portion CH2, and at a boundary between the second portion CH2 and the third portion CH3. A width WU1 of an uppermost part of the first portion CH1 is different from a width WL2 of a lowermost part of the second portion CH2. The width WU1 of the uppermost part of the first portion CH1 is smaller than the width WL2 of the lowermost part of the second portion CH2. A width WU2 of the uppermost part of the second portion CH2 is different from a width WL3 of the lowermost part of the third portion CH3. The width WU2 of the uppermost part of the second portion CH2 is greater than the width WL3 of the lowermost part of the third portion CH3.

The width WL3 of the lowermost part of the third portion CH3 is greater than the thickness T of the conductive film 122.

On the upper side of the cell substrate 100, a vertical center C3 of the third portion CH3 is shifted from a vertical center C1 of the first portion CH1. The vertical centers C1 and C3 may mean centers in a planar point of view parallel to the upper side of the cell substrate 100. The vertical center C3 of the third portion CH3 is not disposed on an extension line extending in the third direction Z from the vertical center C1 of the first portion CH1. For example, the vertical center of the second portion CH2 may coincide with the vertical center C3 of the third portion CH3.

A string separation structure may separate the string selection line 132. The memory cell blocks (BLK1 to BLKn of FIG. 1) defined by the word line cutting structure WLC may be divided by the string separation structure to form a plurality of cell strings (CSTR of FIG. 2). In some embodiments, at least one third portion CH3 may be shifted in a direction away from the string separation structure that does not overlap the word line cutting structure WLC. For example, the vertical center C3 of the third portion CH3 may be shifted in the direction away from the string separation structure that does not overlap the word line cutting structure WLC in the third direction Z, on the basis of the vertical center C1 of the first portion CH1. This makes it possible to secure a region in which the string separation structure is formed. The word line cutting structure WLC may include a word line cutting insulator.

For example, an amount by which the vertical center C3 of the third portion CH3 is shifted on the basis of the vertical center C1 of the first portion CH1 may be different for each third portion CH3. As still another example, among the third portions CH3 disposed between adjacent string separation structures, only the third portion CH3 closest to the string separation structures may be shifted in the direction away from the string separation structure.

The channel structure CS may fill the channel hole CH. Accordingly, the channel structure CS may intersect the plurality of gate electrodes 112, the conductive film 122, and the string selection line 132 in the vertical direction.

Referring to FIG. 3, in some embodiments, the plurality of channel structures CS may be arranged in the form of zigzag. For example, the plurality of channel structures CS may be arranged alternately with each other in the first direction X and the second direction Y. Such channel structures CS may further improve the degree of integration of the semiconductor memory device. The number, placement, and the like of the channel structures CH are merely exemplary and are not limited to those shown. In some other embodiments, the plurality of channel structures CH may be arranged in the form of honeycomb.

Referring to FIGS. 4 and 5 again, in some embodiments, the channel structure CS may include a composite storage layer and a core insulating layer 162. The composite storage layer may include a blocking insulating layer 152, a charge storage layer 154, an insertion layer 156, a tunnel insulating layer 158 and a channel layer 164.

Each of the composite storage layers may conformally and continuously extend along the sidewall profile of a respective channel hole CH from a topmost end to a bottommost end of the channel hole. The composite storage layer may partially fill the channel hole CH. The core insulating layer 162 may fill the remaining portion of the channel hole CH. For example, the blocking insulating layer 152, the charge storage layer 154, the insertion layer 156, the tunnel insulating layer 158, the channel layer 164, and the core insulating layer 162 may be sequentially stacked in the channel hole CH. For example, the blocking insulating layer 152, the charge storage layer 154, the insertion layer 156, the tunnel insulating layer 158, and the channel layer 164 may conformally extend along the profile of the channel hole CH. The core insulating layer 162 may fill the region of the channel hole CH that remains after the blocking insulating layer 152, the charge storage layer 154, the insertion layer 156, the tunnel insulating layer 158, and the channel layer 164 are buried.

The blocking insulating layer 152 may include or be formed of, for example, silicon oxide or a high dielectric constant material having a higher dielectric constant than silicon oxide (e.g., aluminum oxide (Al2O3) and hafnium oxide (HfO2)). The blocking insulating layer 152 may include, for example, silicon oxide. The charge storage layer 154 may include, for example, silicon nitride. The tunnel insulating layer 158 may include or be formed of, for example, silicon oxide or a high dielectric constant material (e.g., aluminum oxide (Al2O3) and hafnium oxide (HfO2)) having a higher dielectric constant than silicon oxide. The tunnel insulating layer 158 may include, for example, silicon oxide.

The insertion layer 156 may be disposed between the blocking insulating layer 152 and the tunnel insulating layer 158. In some embodiments, the insertion layer 156 may be disposed between the charge storage layer 154 and the tunnel insulating layer 158. In some embodiments, the insertion layer 156 includes or be formed of a ferroelectric layer 156a. The ferroelectric layer 156a may surround the tunnel insulating layer 158. The ferroelectric layer 156a may extend conformally along an outer side face of the tunnel insulating layer 158. Accordingly, the insertion layer extends continuously from a topmost end to a bottommost end of the channel hole C, and the insertion layer is conformally formed along a side wall of the channel hole. As used herein, spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. The spatially relative terms (or any other form or variation of the terms) are defined on the basis of the third direction Z.

The ferroelectric layer 156a may include or be formed of ferroelectrics. The ferroelectrics means a material which has a spontaneous polarization and the direction of polarization is changed by an external electric field. For example, the ferroelectric layer 156a may include or be formed of at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

The channel layer 164 may be interposed between the core insulating layer 162 and the tunnel insulating layer 158. One channel layer 164 may intersect the gate electrodes 112, the conductive film 122, and the string selection line 132 in the vertical direction. For example, the channel layer 164 may have a hollow barrel shape (e.g., a cylindrical shape). One end of the channel layer 164 may be electrically connected to a common source line (e.g., CSL of FIG. 2). As an example, when the cell substrate 100 is provided as a common source line, one end of the channel layer 164 may be connected to the cell substrate 100. In the drawing, although the lower side of the channel layer 164 is only shown as being disposed on the same plane as the upper side of the cell substrate 100, this is merely an example. As another example, a lower part of the channel layer 164 may be buried in the cell substrate 100, and the lower side of the channel layer 164 may be disposed to be lower than the upper side of the cell substrate 100.

The channel layer 164 may include or be formed of, for example, but not limited to, semiconductor materials such as single crystal silicon, polycrystalline silicon, organic semiconductor matters, and carbon nanostructures.

The core insulating layer 162 extends in the third direction Z. The core insulating layer 162 may have, for example, a pillar shape. The core insulating layer 162 may include, for example, but not limited to, at least one of silicon oxide, silicon nitride, and silicon oxynitride. As an example, the core insulating layer 162 may include silicon oxide.

In some embodiments, the channel structure CS may include seams S1 and S2 or voids inside. For example, a seam S1 may be formed inside the channel structure CS that fills the first portion CH1 of the channel hole CH, and a seam S2 may be formed inside the channel structure CS that fills the second portion CH2 of the channel hole CH. The positions of the seams S1 and S2 may be formed at various positions inside the channel structure CS. On the other hand, the channel structure CS may not include the seams S1 and S2 therein.

During operation of the memory cell array, a first voltage may be applied to the conductive film 122. For example, the first voltage may be the same as a second voltage applied to the string selection line SSL. By applying a voltage bias to the conductive film 122, a current flow through the channel structure CS (i.e., channel layer) may be facilitated. For example, the current flow may be from the first portion CHI to the third portion CH3 (or vice versa) through the second portion CH2. In an embodiment, conductive film 122 may act as a gate electrode of a transistor in the region of the second portion CH2 and vicinity thereof.

Referring to FIG. 7, in some embodiments, the channel structure CS penetrating the gate electrode 112 may not include a bent part, as shown at R31. In some embodiments, the channel structure CS penetrating the gate electrode 112 may include a bent part, as shown at R32. For example, the channel structure CS may include a lower channel LCS and an upper channel UCS that are connected to each other. At a boundary between the lower channel LCS and the upper channel UCS, a width of the lower channel LCS may be greater than a width of the upper channel UCS. The channel structure CS may have a bent part at the boundary between the lower channel LCS and the upper channel UCS. For example, the gate electrodes 112 that form the boundary between the lower channel LCS and the upper channel UCS may be a dummy word line. Data may not be stored in the memory cells connected to the dummy word line. The voltage level applied to the dummy word line may be different from the voltage level applied to the general word line. The number of gate electrodes 112 through which the shown lower channel LCS passes, and the number of gate electrodes 112 through which the upper channel UCS passes are merely exemplary and not limited thereto.

Referring to FIGS. 3 to 5 again, the word line cutting structure WLC may extend in the first direction X to cut the gate electrodes 112 and the mold insulating films 110. The gate electrodes 112 and the mold insulating films 110 may be divided by the word line cutting structure WLC to form a plurality of memory cell blocks (e.g., BLK1 to BLKn of FIG. 1). The plurality of word line cutting structures WLC may be arranged two-dimensionally in a plane including the first direction X and the second direction Y. For example, the word line cutting structures WLC each extend in the first direction X, and may be spaced apart from each other and arranged along the second direction Y.

The word line cutting structure WLC may include or be formed of an insulating material, for example, but not limited to, at least one of silicon oxide, silicon nitride, and silicon oxynitride.

In some embodiments, the word line cutting structure WLC may not cut the conductive film 122 and the string selection line 132. Accordingly, the upper side of the word line cutting structure WLC may be disposed below the upper side of the channel structure CS.

The bit line BL may be formed on the mold structure MS. The plurality of bit lines BL may be arranged two-dimensionally in a plane including the first direction X and the second direction Y. For example, the bit lines BL may each extend in the second direction Y, and may be spaced apart from each other and arranged along the first direction X.

The bit line BL extends in the second direction Y, and may be connected to a plurality of channel structures CS arranged along the second direction Y. For example, a channel pad 166 connected to the channel structure CS may be formed on the channel structure CS. Further, a bit line contact 168 connected to the channel pad 166 may be formed in the second cell insulating film 142. The bit line BL may be electrically connected to the channel structures CS through the channel pad 166 and the bit line contact 168.

The other end of the channel layer 164 may be electrically connected to the bit line BL. For example, the channel pad 166 may be connected to the upper side of the channel layer 164. Accordingly, the channel layer 164 may electrically connect the common source line (e.g., CSL of FIG. 2) and the bit line BL. For example, when the cell substrate 100 is provided as a common source line, the channel layer 164 may electrically connect the cell substrate 100 and the bit line BL.

Although the channel pad 166 is shown as being connected to the upper side of the channel layer 164, this is only an example. As another example, the channel layer 164 may extend along the side faces of the channel pad 166.

The cell contact 172 may be disposed on the extension region EXT. The cell contact 172 may extend in the third direction Z and penetrate the gate electrodes 112 and the mold insulating films 110. Each cell contact 172 may be electrically connected to each gate electrode 112 through a connecting region CR. For example, the cell contact 172 may penetrate the connecting region CR of the corresponding gate electrode 112, and the side face of the cell contact 172 may be in contact with the inner side face of the connecting region CR of the corresponding gate electrode 112.

For example, the cell contact 172 may include a penetrating part 172a and a protruding part 172b. The penetrating part 172a may extend in the third direction Z and penetrate the gate electrodes 112 and the mold insulating films 110. For example, the penetrating part 172a may be a pillar-shaped (for example, cylindrical) structure. In some embodiments, the width of the penetrating part 172a may decrease toward the cell substrate 100. The protruding part 172b may protrude from the side face of the penetrating part 172a and come into contact with the connecting region CR. As an example, the inner side face of the protruding part 172b may protrude from the side face of the penetrating part 172a. As an example, the protruding part 172b may be an annular structure that surrounds the side face of the penetrating part 172a. Therefore, the cell contact 172 may be electrically connected to each gate electrode 112.

The insulating pattern 114 may be disposed between the cell contact 172 and the gate electrode 112. The insulating pattern 114 may be disposed between the cell contact 172 and the gate electrodes 112 which are not the connecting region CR. The insulating pattern 114 may be disposed between the gate electrodes 112 whose upper side is not exposed and the cell contact 172. As an example, the insulating pattern 114 may be a ring-shaped structure that surrounds the side faces of the cell contact 172. Therefore, the cell contact 172 is electrically connected to the gate electrode 112 disposed at the uppermost part, and may be electrically separated from the remaining gate electrodes except the gate electrode disposed at the uppermost part.

The insulating pattern 114 may include an insulating material, for example, at least one of silicon oxide, silicon nitride, and silicon oxynitride.

For example, the thickness of the gate electrodes 112 in the connecting region CR may be thicker than the thickness of the gate electrodes 112 in a region other than the connecting region CR. The thickness of the connecting region CR may be thicker than the thickness of other gate electrodes disposed thereunder. Therefore, the thickness of the insulating pattern 114 may be thinner than the thickness of the protruding part 172b.

The cell contact 172, the substrate contact 174, and the I/O contact 176 may each include a conductive material, for example, a metal such as tungsten (W), cobalt (Co) and or nickel (Ni), or a semiconductor material such as silicon.

The substrate contact 174 may be disposed on the extension region EXT. The substrate contact 174 extends in the third direction Z, may penetrate the first interlayer insulating film 120, and may be connected to the cell substrate 100. The width of the substrate contact 174 may decrease toward the cell substrate 100.

The I/O contact 176 may be disposed on the through region THR. The I/O contact 176 extends in the third direction Z, may penetrate the first interlayer insulating film 120, and may be connected to the cell substrate 100. The width of the substrate contact 174 may decrease toward the cell substrate 100.

For example, the cell contact 172, the substrate contact 174, and the I/O contact 176 each may not include a bent part as described using FIG. 7, and may include a bent part as described using R32 of FIG. 7.

The cell wiring structure 180 may be formed on the mold structure MS. For example, the cell wiring structure 180 may be formed in the third cell insulating film 143. First to third studs 173, 175, and 177 may penetrate the second to fourth interlayer insulating films 126, 130, and 136 and the first cell insulating film 141. A first stud 173 may be disposed on the cell contact 172. A second stud 175 may be disposed on the substrate contact 174. A third stud 177 may be disposed on the I/O contact 176. The bit line contact 168 may be disposed on the first to third studs 173, 175 and 177. The cell wiring structure 180 may be electrically connected to the bit lines BL, the cell contacts 172, and/or the substrate contact 174. Accordingly, the cell wiring structure 180 may be electrically connected to the channel structure CS, the gate electrodes 112, and/or the cell substrate 100. The number of layers, placement or the like of the shown cell wiring structure 180 are merely exemplary, and the present invention is not limited thereto.

The peripheral circuit structure PERI may include a peripheral circuit substrate 200, a peripheral circuit element PT, and a peripheral circuit wiring structure 260.

The peripheral circuit substrate 200 may include a semiconductor substrate such as, for example, a silicon substrate, a germanium substrate or a silicon-germanium substrate. Alternatively, the peripheral circuit substrate 200 may include a silicon-on-insulator (SOI) substrate, a germanium-on-insulator (GOI) substrate, or the like.

The peripheral circuit element PT may be formed on the peripheral circuit substrate 200. The peripheral circuit element PT may constitute a peripheral circuit (e.g., 30 of FIG. 1) that controls the operation of the semiconductor memory device. For example, the peripheral circuit element PT may include a control logic (e.g., 37 of FIG. 1), a row decoder (e.g., 33 of FIG. 1), a page buffer (e.g., 35 of FIG. 1), and the like. In the following description, a surface of the peripheral circuit substrate 200 on which the peripheral circuit elements PT are disposed may be called a front side of the peripheral circuit substrate 200. In contrast, a surface of the peripheral circuit substrate 200 opposite to the front side of the peripheral circuit substrate 200 may be called a back side of the peripheral circuit substrate 200.

The peripheral circuit element PT may include, for example, but not limited to, a transistor. For example, the peripheral circuit element PT may include not only various active elements such as a transistor, but also various passive elements such as a capacitor, a resistor and an inductor.

The peripheral circuit wiring structure 260 may be formed on the peripheral circuit element PT. For example, an inter-wiring insulating film 240 may be formed on the front side of the peripheral circuit substrate 200, and the peripheral circuit wiring structure 260 may be formed inside the inter-wiring insulating film 240. The peripheral circuit wiring structure 260 may be electrically connected to the peripheral circuit element PT. The number of layers, placement, and the like of the shown peripheral circuit wiring structure 260 are merely examples, and are not limited thereto.

In some embodiments, the cell structure CELL may be stacked on the peripheral circuit structure PERI. For example, the cell structure CELL may be stacked on the inter-wiring insulating film 240.

In some embodiments, the cell contact 172 and the I/O contact 176 may penetrate the insulating substrate 106 and be connected to the peripheral circuit wiring structure 260, and the substrate contact 174 may penetrate the cell substrate 100 and be connected to the peripheral circuit wiring structure 260. Accordingly, the bit line BL, the gate electrode 112, and/or the cell substrate 100 may be electrically connected to the peripheral circuit element PT.

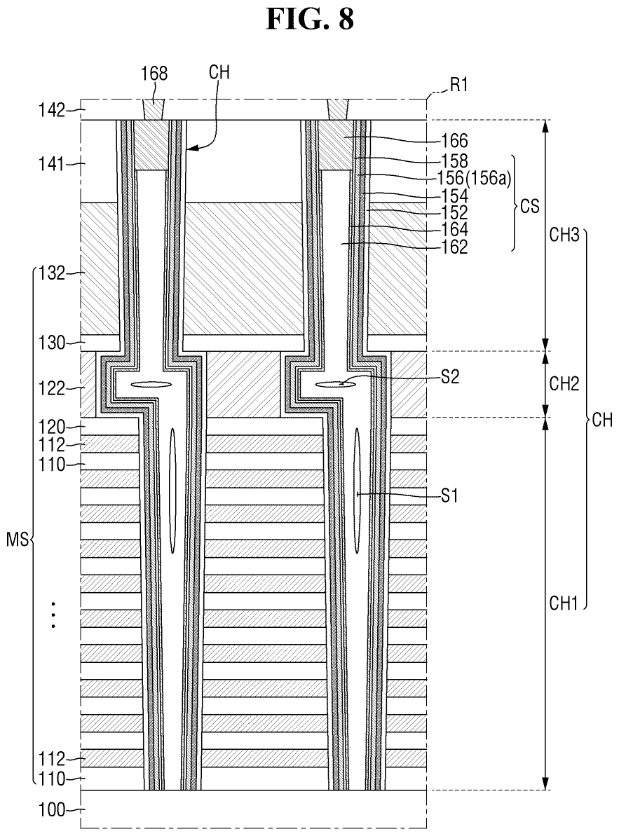

FIGS. 8 to 12 are diagrams for explaining a semiconductor memory device according to some embodiments. For reference, FIGS. 8 to 12 are enlarged views for explaining a region R1 of FIG. 4. For convenience of explanation, repeated parts of those described above using FIGS. 1 to 7 will be briefly explained or omitted.

Referring to FIG. 8, in the semiconductor memory device according to some embodiments, an oxide film (134 of FIG. 5) may not be interposed between the string selection line 132 and the channel structure CS.

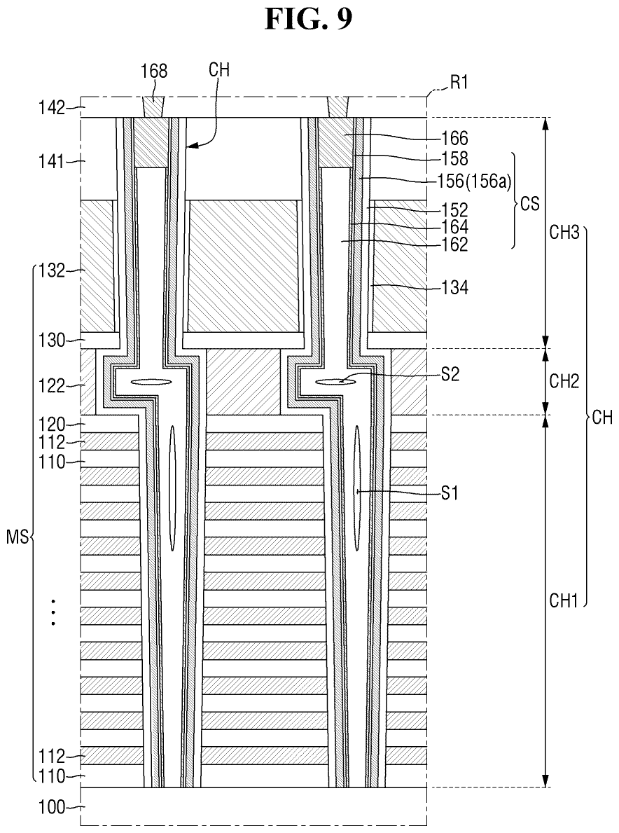

Referring to FIG. 9, in the semiconductor memory device according to some embodiments, the channel structure CS includes a blocking insulating layer 152, an insertion layer 156, a tunnel insulating layer 158, a channel layer 164, and a core insulating layer 162. That is, the charge storage layer 154 of FIG. 5 may be omitted from the composite storage layer.

The blocking insulating layer 152, the insertion layer 156, the tunnel insulating layer 158, the channel layer 164, and the core insulating layer 162 may be sequentially stacked in the channel hole CH. For example, the blocking insulating layer 152, the insertion layer 156, the tunnel insulating layer 158, and the channel layer 164 may extend conformally along the profile of the channel hole CH. The core insulating layer 162 may fill the region of the channel hole CH that remains after the blocking insulating layer 152, the insertion layer 156, the tunnel insulating layer 158, and the channel layer 164 are filled.

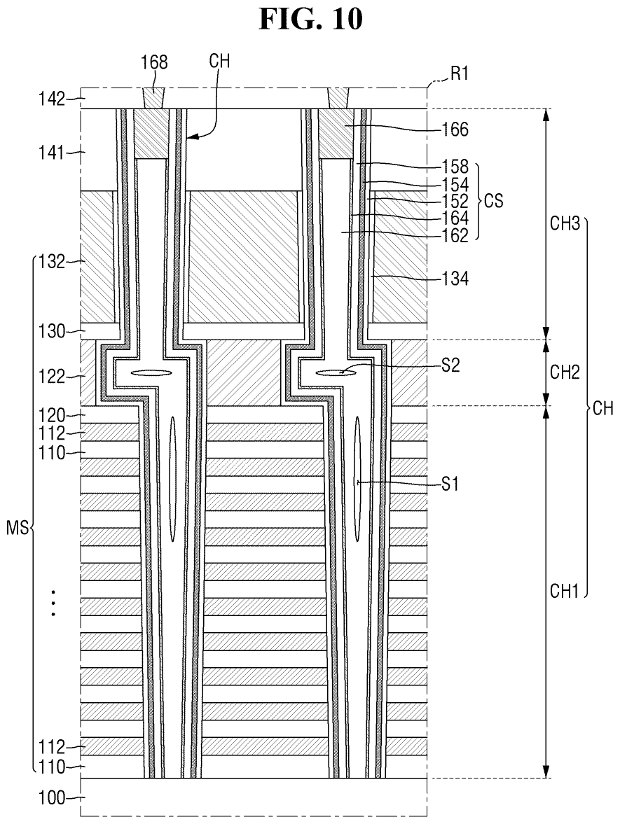

Referring to FIG. 10, in the semiconductor memory device according to some embodiments, the channel structure CS includes the blocking insulating layer 152, the charge storage layer 154, the tunnel insulating layer 158, the channel layer 164, and the core insulating layer 162. That is, the insertion layer 156 of FIG. 5 may be omitted from the composite storage layer.

The blocking insulating layer 152, the tunnel insulating layer 158, the channel layer 164, and the core insulating layer 162 may be sequentially stacked inside the channel hole CH. For example, the blocking insulating layer 152, the tunnel insulating layer 158, and the channel layer 164 may extend conformally along the profile of the channel hole CH. The core insulating layer 162 may fill the region of the channel hole CH that remains after the blocking insulating layer 152, the tunnel insulating layer 158, and the channel layer 164 are filled.

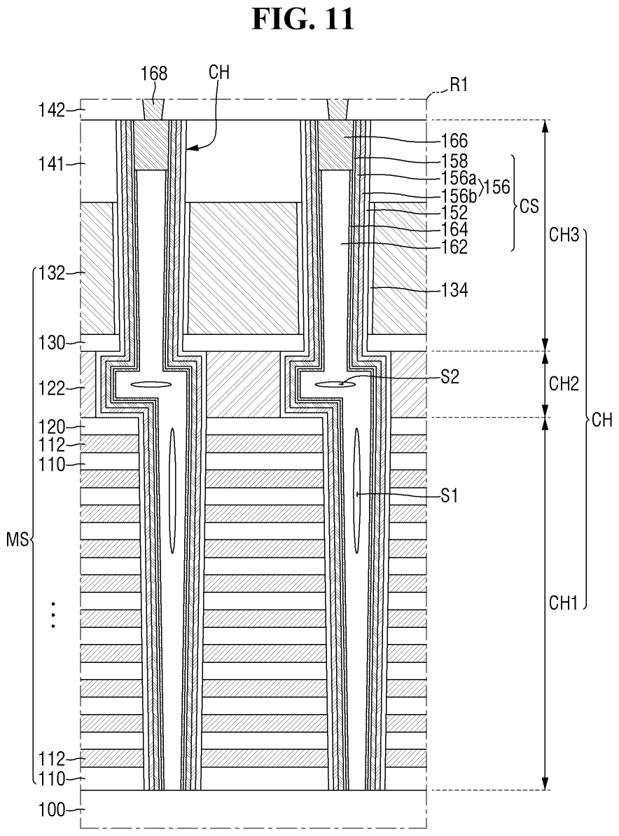

Referring to FIG. 11, in the semiconductor memory device according to some embodiments, the insertion layer 156 of the channel structure CS may include or be formed of a ferroelectric layer 156a and an antiferroelectric layer 156b.

The antiferroelectric layer 156b may include or be formed of antiferroelectrics. The antiferroelectrics refer to a material that does not have a spontaneous polarization in a state in which no external electric field is applied, but has a direction of polarization that changes like ferroelectrics when an external electric field is applied. For example, the antiferroelectric layer 156b may include or be formed of, but not limited to, PbZrO₃ or the like.

In some embodiments, the antiferroelectric layer 156b may be interposed between the ferroelectric layer 156a and the blocking insulating layer 152. The antiferroelectric layer 156b may surround the ferroelectric layer 156a. The antiferroelectric layer 156b may extend conformally along the outer side face of the ferroelectric layer 156a. Such an insertion layer 156 may correspond to the insertion layer 156 of FIGS. 5 and 8.

In some other embodiments, the antiferroelectric layer 156b may be interposed between the tunnel insulating layer 158 and the ferroelectric layer 156a. The antiferroelectric layer 156b may surround the tunnel insulating layer 158. The antiferroelectric layer 156b may extend conformally along the outer side face of the tunnel insulating layer 158. The ferroelectric layer 156a may surround the antiferroelectric layer 156b. The ferroelectric layer 156a may extend conformally along the outer side face of the antiferroelectric layer 156b. Such an insertion layer 156 may correspond to the insertion layer 156 of FIGS. 5 and 8.

In some other embodiments, the insertion layer 156 may have a super lattice structure in which the ferroelectric layers 156a and the antiferroelectric layers 156b are alternately stacked on the side faces of the tunnel insulating layer 158. Such an insertion layer 156 may correspond to the insertion layer 156 of FIGS. 5 and 8.

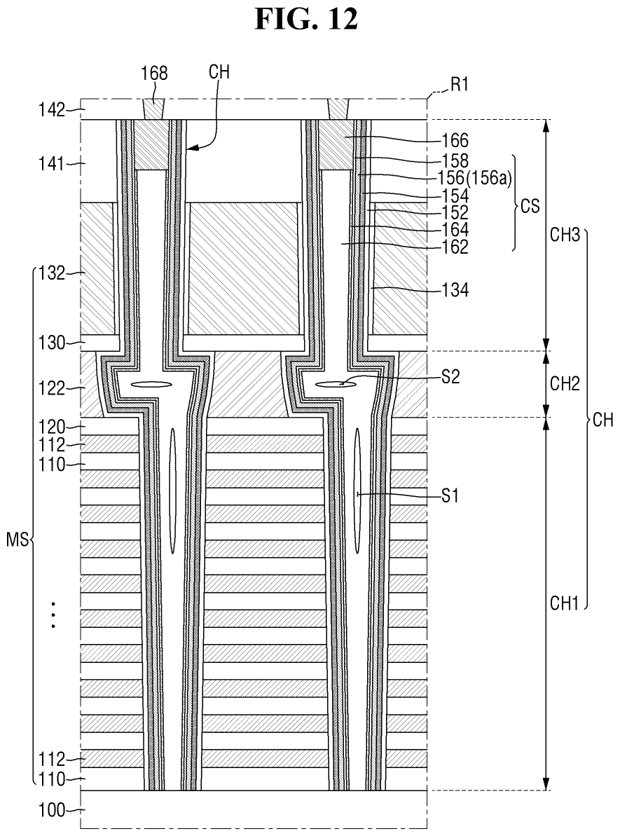

Referring to FIG. 12, in the semiconductor memory device according to some embodiments, at least a part of the side wall of the second portion CH2 of the channel hole CH may be rounded in the vertical direction. For example, the width of the second portion CH2 of the channel hole CH may decrease toward the cell substrate 100. This may be due to the process of forming the second portion CH2 of the channel hole CH. Slopes of the tangent lines along at least a part of the vertical sidewall of the second portion CH2 may gradually change. For example, slopes of the tangent lines along at least a part of the vertical sidewall of the second portion CH2 may gradually decrease toward the cell substrate 100.

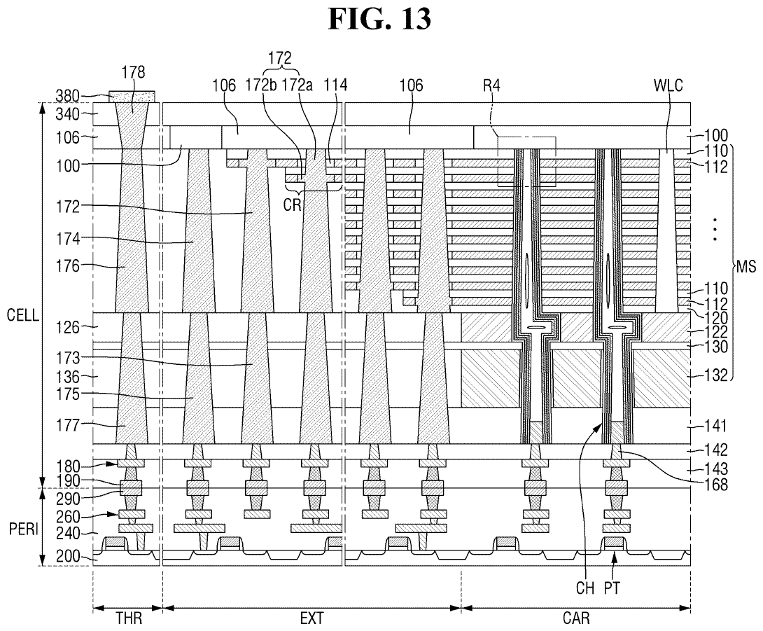

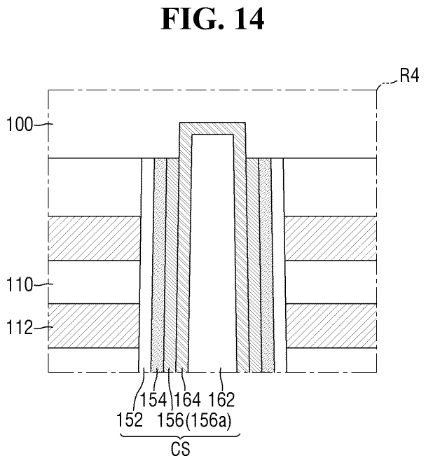

FIG. 13 is a diagram for explaining a semiconductor memory device according to some embodiments. FIG. 14 is an enlarged view of a region R4 of FIG. 13. For reference, FIG. 13 is a cross-sectional view taken along line A-A of FIG. 3. For convenience of explanation, repeated parts of those described above using FIGS. 1 to 7 will be briefly explained or omitted.

Referring to FIG. 13, the front side of the cell substrate 100 is opposite to the front side of the peripheral circuit substrate 200 in the semiconductor memory device according to some embodiments.

The semiconductor memory device according to some embodiments may have a C2C (chip to chip) structure. The C2C structure may mean a structure in which an upper chip including a cell structure CELL is fabricated on a first wafer (e.g., the cell substrate 100) and a lower chip including a peripheral circuit structure PERI is fabricated on a second wafer (e.g., the peripheral circuit substrate 200) different from the first wafer, and then, the upper chip and the lower chip are connected to each other by a bonding way.

As an example, the bonding way may mean a way of electrically connecting a first bonding metal 190 formed on the uppermost metal layer of the upper chip and a second bonding metal 290 formed on the uppermost metal layer of the lower chip. For example, when the first bonding metal 190 and the second bonding metal 290 are formed of copper (Cu), the bonding way may be a Cu—Cu bonding way. However, this is only an example, and the first bonding metal 190 and the second bonding metal 290 may, of course, be formed of various other metals such as aluminum (Al) or tungsten (W).

As the first bonding metal 190 and the second bonding metal 290 are bonded, the cell wiring structure 180 may be connected to the peripheral circuit wiring structure 260. Therefore, the bit line BL, the gate electrodes 112 and/or the cell substrate 100 may be electrically connected to the peripheral circuit element PT.

In some embodiments, an I/O wiring structure 380 may be formed on the back side of the cell substrate 100. The number of layers, placement, and the like of the shown I/O wiring structure 380 are merely examples, and are not limited thereto. The I/O wiring structure 380 may be electrically connected to the cell structure CELL and/or the peripheral circuit structure PERI.

In some embodiments, the I/O contact 176 which connects the cell wiring structure 180 and the I/O wiring structure 380 may be formed. The I/O contact 176 may be formed on the through region THR. The I/O contact 176 may extend, for example, in the third direction Z and penetrate the fifth interlayer insulating film 340 and the insulating substrate 106, and may be connected to the I/O contact 176. The cell wiring structure 180 may be electrically connected to the I/O wiring structure 380 through the I/O contact 176. For example, the width of the I/O contact 176 may decrease toward the first interlayer insulating film 120.

The I/O wiring structure 380 may include a conductive material. As an example, the I/O wiring structure 380 may include aluminum (Al).

The channel structure that fills the channel hole CH of FIG. 13 may correspond to the channel structure CS described above using FIGS. 5 to 12.

Referring to FIG. 14, a part of the channel layer 164 may be disposed in the cell substrate 100. A lower side of the channel layer 164 may be disposed in the cell substrate 100. The blocking insulating layer 152, the charge storage layer 154, and the insertion layer 156 may expose the lower part of the channel layer 164. The lower side of the channel layer 164 may be disposed below the lower sides of the blocking insulating layer 152, the charge storage layer 154, and the insertion layer 156. A part of the lower side or side face of the channel layer 164 may be in contact with the cell substrate 100. Therefore, one end of the channel layer 164 may be electrically connected to a common source line (e.g., CSL of FIG. 2).

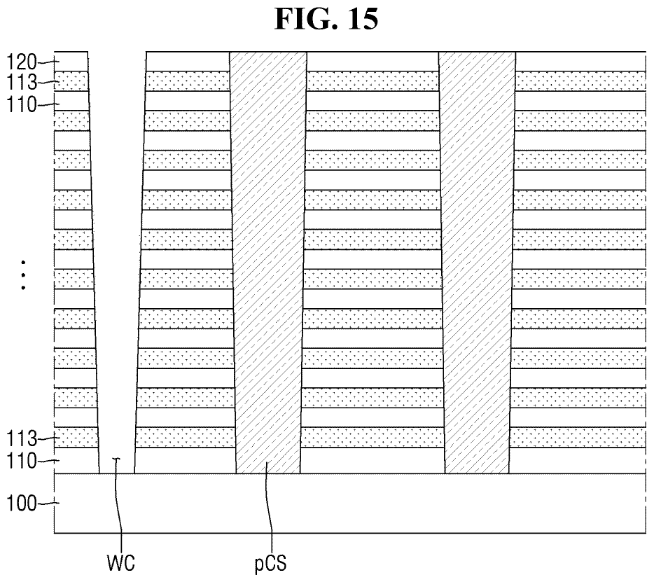

FIGS. 15 to 21 are intermediate step diagrams for explaining a method for fabricating a semiconductor memory device according to some embodiments. For reference, FIGS. 15 to 21 are diagrams showing the cell array region CAR. For convenience of explanation, repeated parts of those described above using FIGS. 1 to 14 will be briefly explained or omitted.

Referring to FIG. 15, mold insulating films 110 and mold sacrificial films 113 are formed on the cell substrate 100. The mold insulating films 110 and the mold sacrificial films 113 may be alternately stacked on the cell substrate 100. The mold sacrificial films 113 may include a material having an etching selectivity with respect to the mold insulating film 110. As an example, the mold insulating film 110 may include a silicon oxide film, and the mold sacrificial film 113 may include a silicon nitride film. The mold insulating films 110 and the mold sacrificial films 113 on the extension region (EXT of FIG. 3) may be patterned in a stepwise pattern. The term “etching selectivity” as used herein refers to the ratio of the etching rates of two different materials with respect to a certain specific etching process. When “a material A has an etching selectivity with respect to a material B,” it should be appreciated that a certain specific etching process removes a significant amount of the material B while providing little or no removal of the material A or vice versa.

The first interlayer insulating film 120 may cover the mold insulating films 110 and the mold sacrificial films 113.

A preliminary channel pCS which penetrates the first interlayer insulating film 120, the mold insulating films 110, and the mold sacrificial films 113 is formed. The preliminary channel pCS may be connected to the cell substrate 100. The preliminary channel pCS may include a material having an etching selectivity with respect to the mold insulating films 110 and the mold sacrificial films 113. As an example, the preliminary channel pCS may include polysilicon (poly—Si).

A word line cutting region WC which penetrates the first interlayer insulating film 120, the mold insulating films 110, and the mold sacrificial films 113 is formed. The word line cutting region WC may extend in a first direction (e.g., X of FIG. 3) and cut the first interlayer insulating film 120, the mold insulating film 110, and the mold sacrificial film 113.

In some embodiments, the preliminary channel hole and the word line cut region WC may be formed simultaneously. Next, a preliminary channel pCS that fills the preliminary channel hole may be formed. In some other embodiments, each of the preliminary channel hole and the word line cut region WC may be formed by different processes.

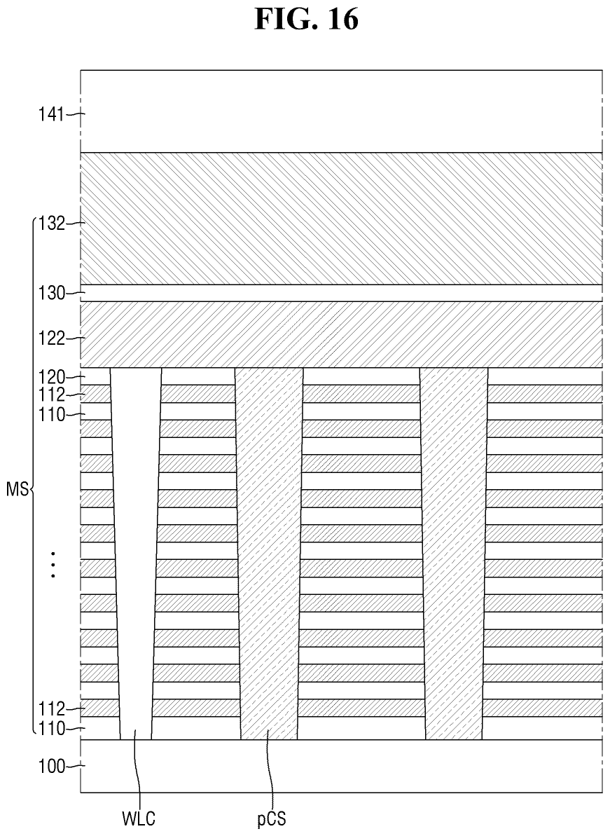

Referring to FIGS. 15 and 16, gate electrodes 112 are formed. The gate electrodes 112 may be formed through a replacement process. The mold sacrificial films 113 exposed by the word line cutting region WC may be selectively removed. The gate electrodes 112 which replace the region in which the mold sacrificial films 113 are removed may then be formed.

Next, the word line cutting structure WLC that fills the word line cutting region WC is formed. For example, a word line cutting insulator may fill the word line cutting region WC.

Next, a conductive film 122, a third interlayer insulation film 130, a string selection line 132, and a first cell insulating film 141 are sequentially formed on the first interlayer insulation film 120. At this time, the second interlayer insulating film 126, the third interlayer insulating film 130, the fourth interlayer insulating film 136, and the first cell insulating film 141 may be formed sequentially in the extension region (EXT of FIG. 4) and the penetration region (THR of FIG. 4).

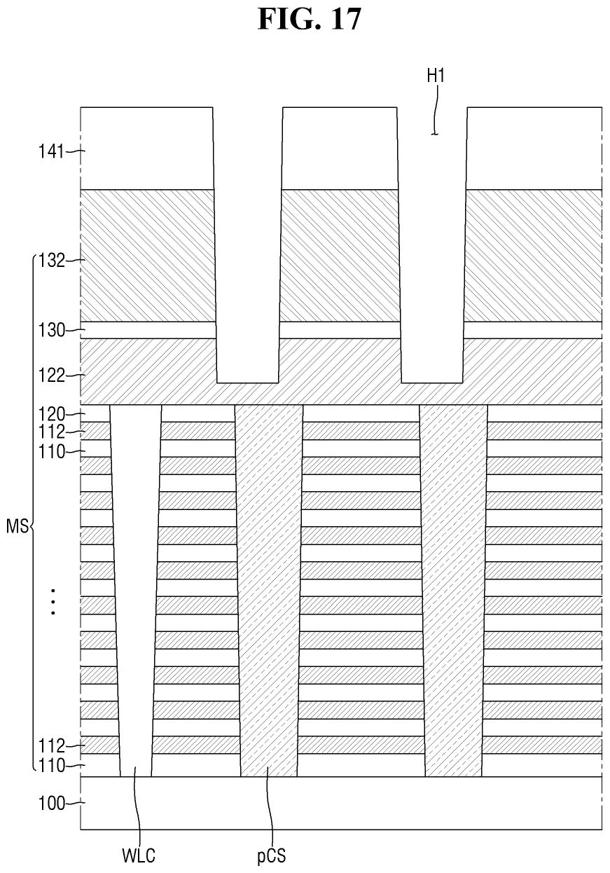

Referring to FIG. 17, a first hole H1 is formed.

The first hole H1 may penetrate the first cell insulating film 141, the string selection line 132, and the third interlayer insulating film 130. The conductive film 122 includes or be formed of a different material from the string selection line 132. The conductive film 122 may include or be formed of a material having an etching selectivity with respect to the string selection line 132. The conductive film 122 may function as an etching stop film in the process of forming the first hole H1. A bottom face of the first hole H1 may be formed in the conductive film 122. At this time, a vertical center of the first hole H1 may be shifted from a vertical center of the preliminary channel pCS on the upper side of the cell substrate 100.

Before the first hole H1 is formed, the cell contact 172, the substrate contact 174, and the I/O contact 176 of FIGS. 4 and 13 may be formed. In some embodiments, the preliminary cell contact hole in which the cell contact 172 is formed, the preliminary substrate contact hole in which the substrate contact 174 is formed, and the preliminary I/O contact hole in which the I/O contact 176 is formed may be formed simultaneously with the preliminary channel hole in which the preliminary channel pCS is formed. In some other embodiments, each of the preliminary cell contact holes, the preliminary substrate contact hole, and the preliminary I/O contact hole may be formed by different processes from the preliminary channel hole.

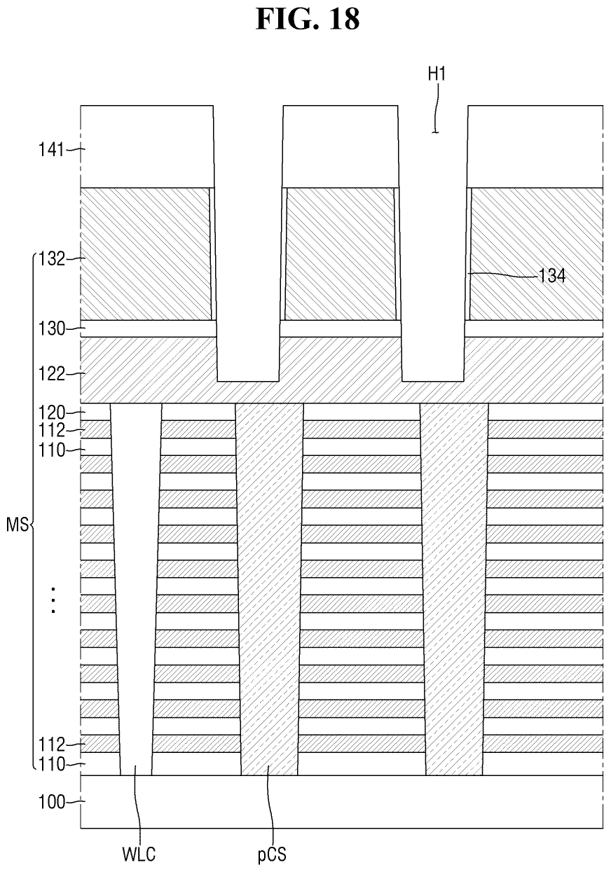

Referring to FIG. 18, an SSL protection film 134 may be formed. The SSL protection film 134 may be formed by oxidizing a part of the string selection line 132 exposed through the first hole H1.

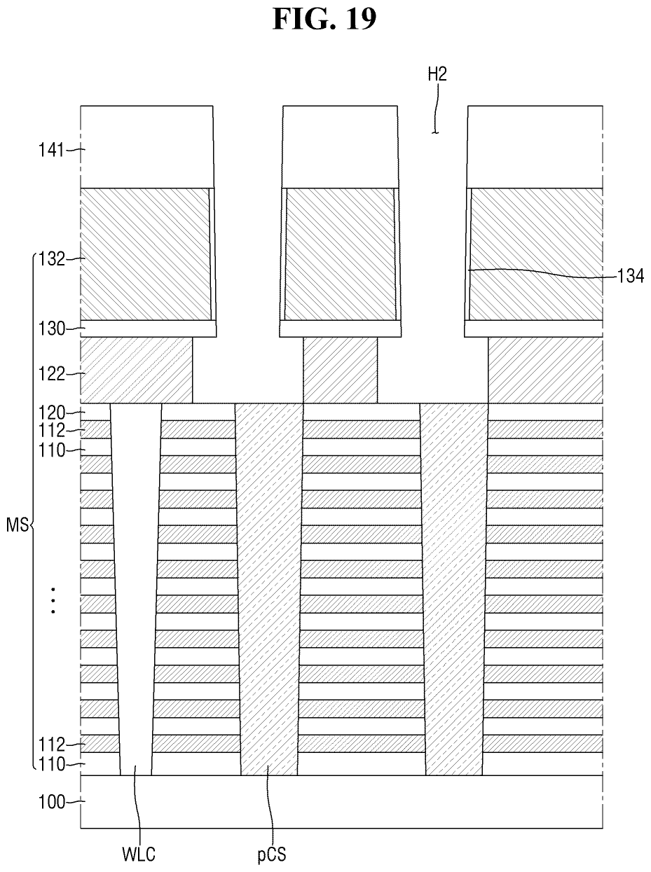

Referring to FIGS. 18 and 19, a second hole H2 is formed. The second hole H2 may be formed by removing the conductive film 122 through the first hole H1. The second hole H2 may expose at least a part of the preliminary channel pCS.

The conductive film 122 may be removed by, for example, a wet etching process. Therefore, at least a part of the side wall of the second hole H2 in the conductive film 122 may be rounded. In this case, as shown in FIG. 12, a second portion CH2 of the channel hole CH may be formed in which at least a part of the side wall is rounded.

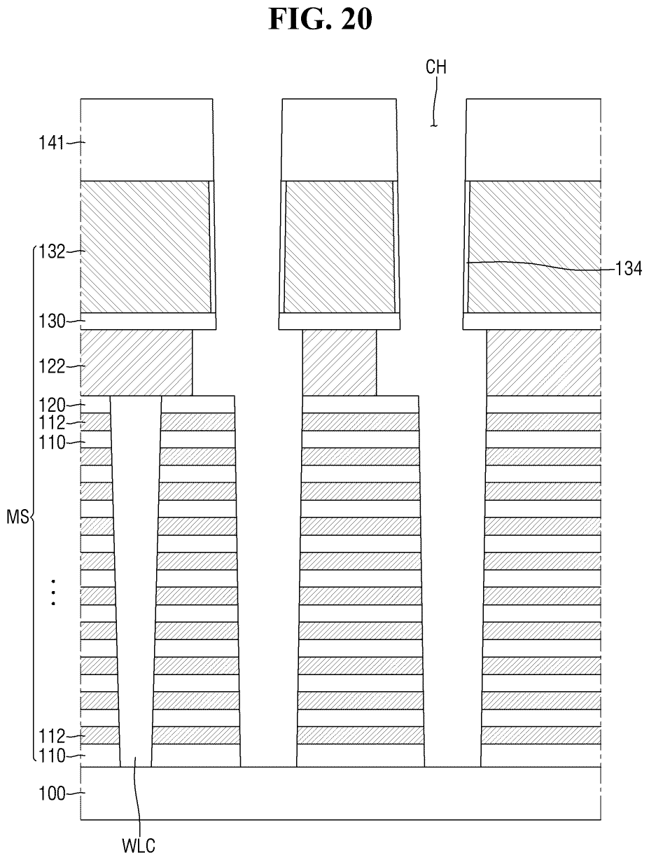

Referring to FIGS. 19 and 20, the preliminary channel pCS is removed through the second hole H2. As a result, a channel hole CH is formed. The channel hole CH includes a first portion CH1, a second portion CH2, and a third portion CH3, as in FIG. 5.

At this time, even if the string selection line 132 and the preliminary channel pCS include the same material, since the SSL protection film 134 is formed on the string selection line 132 exposed by the second hole H2, the string selection line 132 may not be removed in the process of removing the preliminary channel pCS.

When the string selection line 132 includes or be formed of a material having an etching selectivity with respect to the preliminary channel pCS, the process of forming the SSL protection film 134 may be omitted. In this case, the channel structure CS described above using FIG. 8 may be formed.

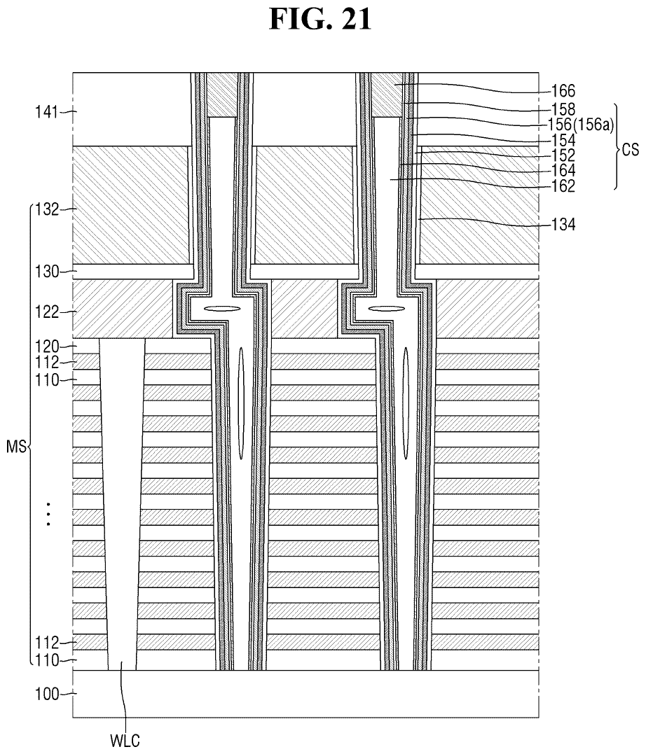

Referring to FIGS. 20 and 21, the channel structure CS that fills the channel hole CH is formed. Furthermore, a channel pad 166 connected to the channel layer 164 may be formed on the channel structure CS. Accordingly, the channel structure CS described above using FIGS. 5 to 12 may be formed. The channel structure CS may extend in the third direction Z, and may be continuously connected from the string selection line 132 to the gate electrodes 112. The channel structure CS may intersect the string selection line 132 and the gate electrodes 112 in the vertical direction. The channel structure CS may have the same film configuration at each position thereof adjacent to of the string selection line 132, the conductive film 122, and the gate electrode 112. Additionally, one channel pad 166 may be formed on the top of the channel structure CS.

In some embodiments, referring to FIGS. 21 and 13, a bit line contact 168, a bit line BL, a cell wiring structure 180, and a first bonding metal 190 may be formed on channel pad 166.

The peripheral circuit structure PERI may be provided. The peripheral circuit structure PERI may include a peripheral circuit substrate 200, a peripheral circuit element PT, a peripheral circuit wiring structure 260, an inter-wiring insulating film 240, and a second bonding metal 290.

The peripheral circuit structure PERI may be bonded to the front side of the cell substrate 100. The first bonding metal 190 and the second bonding metal 290 may be bonded to each other. Thereafter, the cell substrate 100 may be removed to expose the lower part of the channel structure CS. Referring to FIG. 14, the exposed blocking insulating layer 152, the charge storage layer 154, and the insertion layer 156 may be removed. A part of the channel layer 164 may be exposed, accordingly. Next, the cell substrate 100 connected to the channel structure CS may be formed.

In the semiconductor memory devices according to some embodiments, the channel structure CS penetrating the string selection line 132 and the channel structure CS penetrating the gate electrode 112 are simultaneously formed. Therefore, compared to a case of forming the channel structure penetrating the string selection line 132 and the channel structure penetrating the gate electrode 112 in separate processes, the fabricating cost and/or the fabricating time of the semiconductor memory device can be reduced.

Further, when a channel structure penetrating the gate electrode 112 is formed and then a channel structure penetrating the string selection line 132 is formed in a separate process, after forming the channel structure penetrating the gate electrode 112, a process of applying heat, such as an annealing process, may be performed. For example, the annealing process may be performed in the process of forming the word line cutting structure WLC, the cell contact 172, the substrate contact 174, and/or the I/O contact 176. In this case, the ferroelectrics properties of the ferroelectric layer 156a of the channel structure CS may deteriorate due to heat. However, in the semiconductor memory devices according to some embodiments, the channel structure CS is formed after the cell contact 172, the substrate contact 174, and the I/O contact 176 are formed. Therefore, deterioration of the ferroelectric layer 156a of the channel structure CS may be prevented, and a semiconductor memory device having improved reliability may be provided.

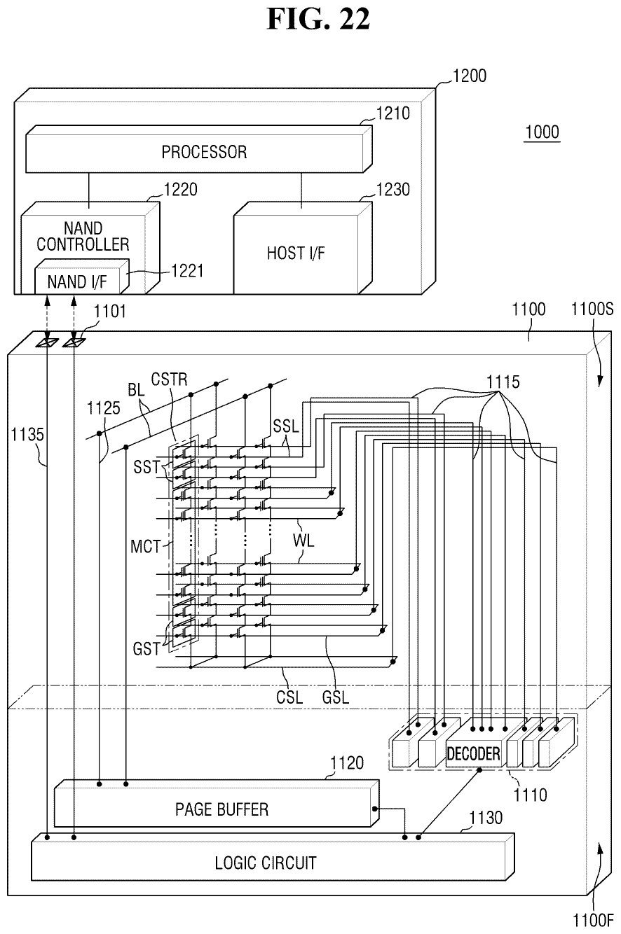

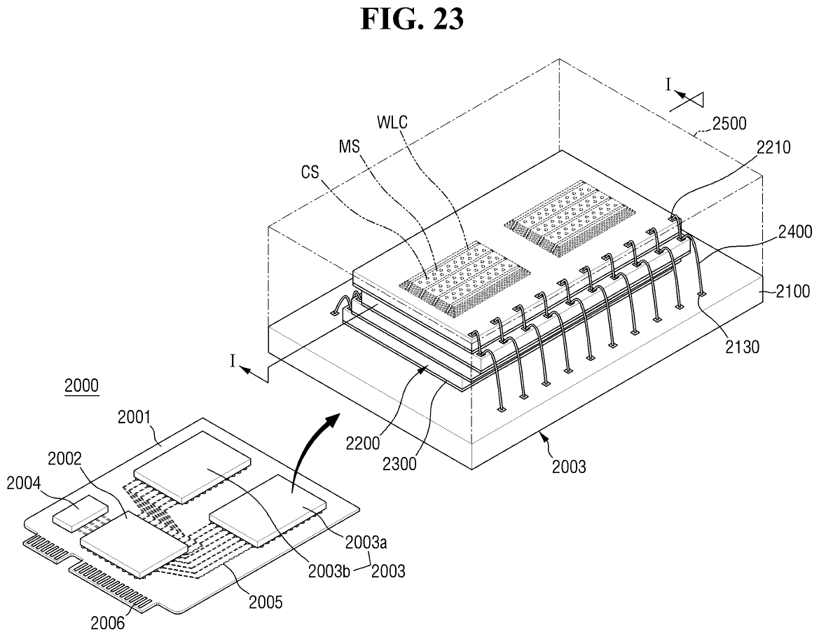

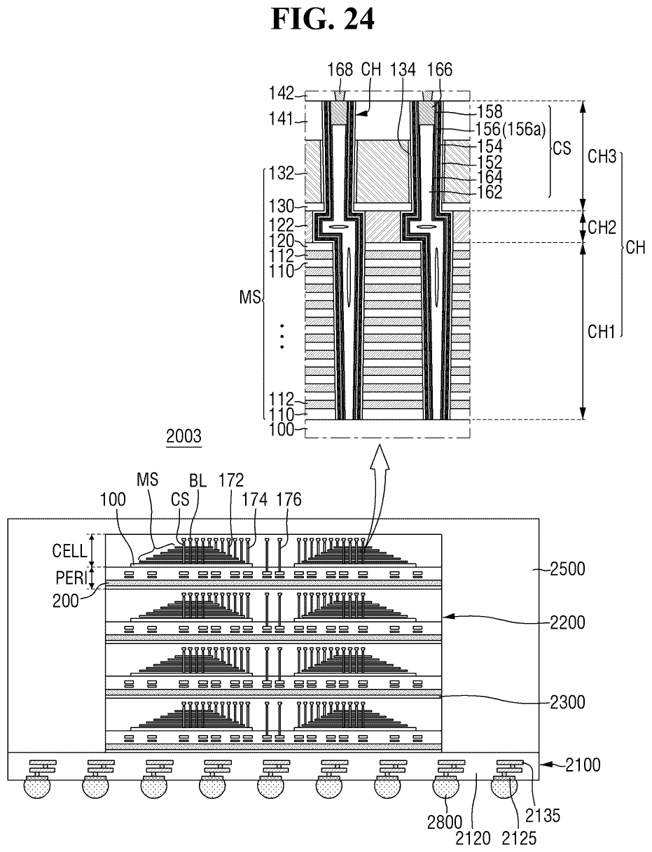

FIG. 22 is an exemplary block diagram for explaining an electronic system according to some embodiments. FIG. 23 is an exemplary perspective view for explaining the electronic system according to some embodiments. FIG. 24 is a schematic cross-sectional view taken along I-I of FIG. 23.

Referring to FIG. 22, an electronic system 1000 according to some embodiments may include a semiconductor memory device 1100 (e.g., 10 n FIG. 1), and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be an SSD device (solid state drive device), a USB (Universal Serial Bus), a computing system, a medical device or a communication device that includes one or multiple semiconductor memory devices 1100.

The semiconductor memory device 1100 may be a non-volatile memory device (e.g., a NAND flash memory device), and may be, for example, the semiconductor memory device explained above using FIGS. 1 to 14. The semiconductor memory device 1100 may include a first structure 1100F, and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may correspond to, for example, the peripheral circuit structure PERI explained above using FIGS. 1 to 14.

The second structure 1100S may include the common source line CSL, the plurality of bit lines BL, and the plurality of cell strings CSTR explained above using FIG. 2. The cell strings CSTR may be connected to the decoder circuit 1110 through the word line WL, at least one string selection line SSL, and at least one ground selection line GSL. In addition, the cell strings CSTR may be connected to the page buffer 1120 through the bit lines BL. The second structure 1100S may correspond to, for example, the cell structure CELL explained above using FIGS. 1 to 14.

In some embodiments, the common source line CSL and the cell strings CSTR may be electrically connected to the decoder circuit 1110 through first connection wirings 1115 extending from the first structure 1100F to the second structure 1100S. In some embodiments, the bit lines BL may be electrically connected to the page buffer 1120 through the second connection wirings 1125. The first connection wiring 1115 and the second connection wiring 1125 may correspond to, for example, different portions of the cell contact 172, the substrate contact 174, and/or the I/O contacts 176 described above using FIGS. 1 to 14.

The semiconductor memory device 1100 may communicate with the controller 1200 through an I/O pad 1101 electrically connected to the logic circuit 1130 (e.g., the control logic 37 of FIG. 1). The I/O pad 1101 may be electrically connected to the logic circuit 1130 through the I/O connection wiring 1135 extending from the inside of the first structure 1100F to the second structure 1100S.

The controller 1200 may include a processor 1210, a NAND controller 1220, and a host interface 1230. In some embodiments, the electronic system 1000 may include a plurality of semiconductor memory devices 1100, and in this case, the controller 1200 may control the plurality of semiconductor memory devices 1100.

The processor 1210 may control the operation of the overall electronic system 1000 including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 23 and 24, an electronic system according to some embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of fins coupled to an external host. In the connector 2006, the number and placement of the plurality of fins may vary depending on the communication interface between the electronic system 2000 and the external host. In some embodiments, the electronic system 2000 may communicate with the external host according to any one of interfaces such as M-Phy for a USB (Universal Serial Bus), a PCI-Express (Peripheral Component Interconnect Express), a SATA (Serial Advanced Technology Attachment), and a UFS (Universal Flash Storage). In some embodiments, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 placed on the lower sides of each of the semiconductor chips 2200, a connecting structure 2400 that electrically connects the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 28.

In some embodiments, the connecting structure 2400 may be a bonding wire that electrically connects the I/O pad 2210 and the package upper pads 2130. Therefore, in each of the first semiconductor package 2003a and the second semiconductor package 2003b, the semiconductor chips 2200 may be electrically connected to each other by a bonding wire type, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire type.

In some embodiments, the main controller 2002 and the semiconductor chips 2200 may also be included in a single package. In some embodiments, the main controller 2002 and the semiconductor chips 2200 are mounted on a separate interposer substrate different from the main board 2001, and the main controller 2002 and the semiconductor chips 2200 may also be connected to each other by wiring formed on the interposer substrate.

In some embodiments, the package substrate 2100 may be a printed circuit board. The package substrate 2100 may include a package substrate body portion 2120, package upper pads 2130 placed on an upper side of the package substrate body portion 2120, lower pads 2125 placed on a lower side of the package substrate body portion 2120 or exposed through the lower side, and inner wirings 2135 that electrically connect the package upper pads 2130 and the lower pads 2125 inside the package substrate body portion 2120. The package upper pads 2130 may be electrically connected to the connecting structures 2400. The lower pads 2125 may be connected to the wiring patterns 2005 of the main board 2001 of the electronic system 2000 through conductive connections 2800 as in FIG. 44.

In the electronic system according to some embodiments, each of the semiconductor chips 2200 may include the semiconductor memory device described above using FIGS. 1 to 14. For example, each of the semiconductor chips 2200 may include a peripheral circuit structure PERI, and a cell structure CELL stacked on the peripheral circuit structure PERI. As an example, the peripheral circuit structure PERI may include the peripheral circuit substrate 200 and the peripheral circuit wiring structure 260 explained above using FIGS. 3 and 4. Further, as an example, the cell structure CELL may include the cell substrate 100, the mold structure MS, the channel structure CS, the bit line BL, the cell contact 172, the substrate contact 174, and the I/O contact 176 explained above using FIGS. 1 to 14. The channel structure CS may also include the blocking insulating layer 152, the charge storage layer 154, the insertion layer 156, the tunnel insulating layer 158, the channel layer 164 and the core insulating layer 162 described above using FIGS. 1 to 14. Furthermore, the SSL protection film 134 described above using FIGS. 1 to 14 may be interposed between the string selection line 132 and the channel structure CS.

Although the embodiments of the present invention have been described above with reference to the accompanying drawings, the present invention is not limited to the above embodiments, and may be fabricated in various different forms. Those skilled in the art will appreciate that the present invention may be embodied in other specific forms without changing the technical spirit or essential features of the present invention. Accordingly, the above-described embodiments should be understood in all respects as illustrative and not restrictive.

1. A semiconductor memory device comprising:
a cell substrate;
a cell array assembly which includes word lines, a voltage bias film, and a string selection line (SSL) stacked sequentially on the cell substrate;
a channel hole which penetrates the cell array assembly; and
a composite storage layer inside the channel hole,
wherein the channel hole includes a first portion penetrating the word lines, a second portion penetrating the voltage bias film, and a third portion penetrating the SSL, and
wherein a width of a lowermost part of the second portion is greater than a width of an uppermost part of the first portion, and a width of an uppermost part of the second portion is greater than a width of a lowermost part of the third portion.

2. The semiconductor memory device of claim 1,
wherein the voltage bias film includes a material different from a material that forms the SSL.

3. The semiconductor memory device of claim 1,
wherein the width of the lowermost part of the third portion is greater than a thickness of the voltage bias film.

4. The semiconductor memory device of claim 1, further comprising a core insulating layer,
wherein the composite storage layer includes a blocking insulating layer, a charge storage layer, a tunnel insulating layer and a channel layer, and the blocking insulating layer, the charge storage layer, the tunnel insulating layer and the channel layer and the core insulating layer are sequentially formed in the channel hole.

5. The semiconductor memory device of claim 1, further comprising a core insulating layer,
wherein the composite storage layer includes a blocking insulating layer, a charge storage layer, a ferroelectric layer, a tunnel insulating layer and a channel layer, and
wherein the blocking insulating layer, the charge storage layer, the ferroelectric layer, the tunnel insulating layer and the channel layer, and the core insulating layer are sequentially formed in the channel hole.

6. The semiconductor memory device of claim 1, further comprising a core insulating layer,
wherein the composite storage layer includes a blocking insulating layer, a ferroelectric layer, a tunnel insulating layer, and a channel layer,
wherein the blocking insulating layer, the ferroelectric layer, the tunnel insulating layer and the channel layer, and the core insulating layer which are sequentially formed in the channel hole.

7. The semiconductor memory device of claim 1, further comprising a core insulating layer,
wherein the composite storage layer includes a blocking insulating layer, an insertion layer, a tunnel insulating layer, and a channel layer, and
wherein the blocking insulating layer, the insertion layer, the tunnel insulating layer and the channel layer, and the core insulating layer are sequentially formed in the channel hole,
wherein the insertion layer includes a ferroelectric layer and an antiferroelectric layer.

8. The semiconductor memory device of claim 1, further comprising:
an SSL protection film between the composite storage layer and the SSL.

9. The semiconductor memory device of claim 1, further comprising:
a channel pad connected to the composite storage layer.

10. The semiconductor memory device of claim 1, further comprising a core insulating layer, the core insulating layer filling the channel hole,
wherein the core insulating layer includes a seam therein.

11. The semiconductor memory device of claim 1,
wherein a vertical center of the first portion of the channel hole does not coincide with a vertical center of the third portion of the channel hole.

12. The semiconductor memory device of claim 1,
wherein at least a part of a side wall of the second portion of the channel hole is rounded in a vertical direction.

13. (canceled)

14. The semiconductor memory device of claim 21, further comprising:
a composite storage layer which includes a channel layer extending along the channel hole; and
a word line cutting insulator which cuts the word lines,
wherein an upper side of the word line cutting insulator is disposed below a topmost end of the composite storage layer.

15. The semiconductor memory device of claim 21,
wherein the composite storage layer further includes a ferroelectric layer.

16. The semiconductor memory device of claim 21,
wherein the composite storage layer further includes a ferroelectric layer and an antiferroelectric layer.

17. The semiconductor memory device of claim 21, further comprising:
an SSL protection film between the composite storage layer and the SSL.

18. The semiconductor memory device of claim 21,
wherein the voltage bias film includes a material having an etching selectivity with respect to the SSL.

19. An electronic system comprising:
a main board;
a semiconductor memory device on the main board; and
a controller on the main board, and electrically connected to the semiconductor memory device,
wherein the semiconductor memory device includes:
a cell substrate;
a cell array assembly which includes word lines, a voltage bias film, and a string select line (SSL) stacked sequentially on the cell substrate;
a channel hole which penetrates the cell array assembly;
a composite storage layer which includes a channel layer extending along the channel hole, and
a channel pad connected to the channel layer, on the composite storage layer, and
wherein the voltage bias film includes a material different from the SSL, and a minimum width of a portion of the channel hole that penetrates the SSL is smaller than a maximum width of a portion of the channel hole that penetrates the voltage bias film.

20. The electronic system of claim 19,
wherein the composite storage layer includes a ferroelectric layer on the channel layer.

21. A semiconductor memory device comprising:
a cell substrate;
a cell array assembly which includes word lines, a voltage bias film and a string select line (SSL) stacked sequentially on the cell substrate;
a channel hole which penetrates the cell array assembly; and
a channel layer in the channel hole,
wherein the channel layer extends along a side wall of the channel hole, the channel layer is formed conformally along the side wall of the channel hole, and the channel layer intersects the word lines, the voltage bias film and the SSL in a vertical direction.

22. (canceled)
